(19) United States
(12) Patent Application Publication
(10) Pub. No.: US 2026/0223584 A1
(43) Pub. Date: Jul. 30, 2026

(54) LIGHT EMITTING DISPLAY DEVICE

(71) Applicant: LG Display Co., Ltd., Seoul (KR)

(72) Inventor: Min Geun CHOI, Paju-si (KR)

(73) Assignee: LG Display Co., Ltd., Seoul (KR)

(21) Appl. No.: 19/453,455

(22) Filed: Jan. 20, 2026

(30) Foreign Application Priority Data
Jan. 24, 2025 (KR) 10-2025-0011980

(51) Int. Cl. H10K 59/80; H10K 59/122; H10K 59/35; H10K 59/38

(52) U.S. Cl. CPC H10K 59/8792; H10K 59/122; H10K 59/35; H10K 59/38

(57) ABSTRACT

A light emitting display device can include a substrate including a plurality of subpixels, each subpixel having a light emitting portion and a non-light emitting portion. The display device further includes a bank configured to open the light emitting portion of each of the plurality of subpixels, a light emitting device at each of the plurality of subpixels, an encapsulation layer configured to cover the light emitting device, an anti-reflective structure comprising a light shielding layer and a color filter, and a refractive reinforcement layer located on the anti-reflective structure while overlapping the color filter.

### CROSS-REFERENCE TO RELATED APPLICATIONS

This application claims priority to Korean Patent Application No. 10-2025-0011980, filed in the Republic of Korea on Jan. 24, 2025, which is hereby expressly incorporated by reference as if fully set forth herein.

### BACKGROUND OF THE DISCLOSURE

### Field of the Disclosure

The present disclosure relates to a light emitting display device with improved transmittance, reduced power consumption, and excellent luminance at a wide range of viewing angles.

### Discussion of the Related Art

With the development of the information society, the demand for display devices for displaying images is increasing in various forms.

A light emitting display device constituting a pixel using a light emitting device has the advantage of not requiring a separate light source unit, which is advantageous for slimness and flexibility, and also has the advantage of good color purity.

In an example, the light emitting device includes two different electrodes and a light emitting layer provided therebetween.

Since the light emitting display device uses light emitted from the light emitting device without a separate light source unit, various studies are being conducted to emit the light emitted from the light emitting device with as little loss as possible and use the same for display.

### SUMMARY OF THE DISCLOSURE

Embodiments of the present disclosure provide a light emitting display device with improved light transmittance while external light reflection is prevented without a polarizer that reduces light transmittance.

Embodiments of the present disclosure provide a light emitting display device with reduced power consumption.

Embodiments of the present disclosure provide a light emitting display device in which a certain degree of luminance efficiency is secured at a wide range of viewing angles, whereby realization of a wide viewing angle is possible.

Embodiments of the present disclosure provide a light emitting display device that prevents color-specific luminance deviation at a wide range of viewing angles, thereby improving visual perception.

A light emitting display device according to an embodiment of the present disclosure includes a substrate including a plurality of subpixels, each having a light emitting portion and a non-light emitting portion, a bank configured to open the light emitting portion of each of the plurality of subpixels, the bank at the non-light emitting portion, a light emitting device at each of the plurality of subpixels, an encapsulation layer configured to cover the light emitting device, an anti-reflective structure comprising a light shielding layer located on the encapsulation layer while overlapping the non-light emitting portion and a color filter located on the encapsulation layer while overlapping the light emitting portion and a refractive reinforcement layer located on the anti-reflective structure while overlapping the color filter, the refractive reinforcement layer having a larger refractive index than the color filter.

### BRIEF DESCRIPTION OF THE DRAWINGS

The accompanying drawings, which are included to provide a further understanding of the present disclosure and are incorporated in and constitute a part of this application, illustrate embodiments of the present disclosure and together with the description serve to explain the principle of the present disclosure. In the drawings:

FIG. 1 is a block diagram schematically showing a light emitting display device according to one or more embodiments of the present disclosure;

FIG. 2 is a plan view showing a light emitting display device according to a first embodiment of the present disclosure;

FIG. 3 is a sectional view taken along line I-I′ of FIG. 2;

FIG. 4 is an example of a graph showing the refractive index by wavelength of a refractive reinforcement layer of an embodiment of the present disclosure;

FIGS. 5A and 5B are graphs showing Au′v′ by viewing angle of first and second experimental examples;

FIG. 6 is a plan view showing a light emitting display device according to a second embodiment of the present disclosure;

FIG. 7 is a sectional view taken along line II-II′ of FIG. 6;

FIG. 8 is a plan view showing a light emitting display device according to a third embodiment of the present disclosure;

FIG. 9 is a sectional view taken along line III-III′ of FIG. 8;

FIG. 10 is a sectional view showing a change of area K of FIG. 3 according to a fourth embodiment of the present disclosure; and

FIGS. 11 and 12 are sectional views showing other examples of a light emitting device of the light emitting display device according to the present disclosure.

### DETAILED DESCRIPTION OF THE DISCLOSURE

The same reference numbers will be used throughout the drawings to refer to the same or like parts. In the following description, detailed descriptions of technologies or configurations related to the present disclosure can be omitted so as to avoid unnecessarily obscuring the subject matter of the present disclosure. In addition, the names of devices used in the following description are selected in consideration of clarity of description of the disclosure, and can differ from the names of devices of actual products.

Advantages and features of the present disclosure, and a method of achieving the advantages and features will become apparent with reference to the example embodiments described herein in detail together with the accompanying drawings. The present disclosure should not be construed as limited to the example embodiments as disclosed below, and can be embodied in various different forms. Thus, these example embodiments are set forth only to make the present disclosure sufficiently complete, and to assist those skilled in the art to fully understand the scope of the present disclosure. The protected scope of the present disclosure is defined by the claims and their equivalents.

In the following description of the present disclosure, where the detailed description of the relevant known steps, elements, functions, technologies, and configurations can unnecessarily obscure an important point of the present disclosure, a detailed description of such steps, elements, functions, technologies, and configurations maybe omitted. In addition, the names of elements used in the following description are selected in consideration of clarity of description of the specification, and can differ from the names of elements of actual products. Furthermore, in the following detailed description of the present disclosure, numerous specific details are set forth in order to provide a sufficiently thorough understanding of the present disclosure. However, it will be understood that the present disclosure can be practiced without these specific details. In other instances, known methods, procedures, components, and circuits have not been described in detail so as not to unnecessarily obscure aspects of the present disclosure.

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items. Further, the term “can” fully encompasses all the meanings and coverages of the term “may” and vice versa.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

As used herein, the term “LUMO (lowest unoccupied molecular orbital) energy level” and “HOMO (highest occupied molecular orbital) energy level” of a layer refer respectively to the LUMO energy level and HOMO energy level of a material that occupies most of a weight ratio of the layer, for example, a host material, unless the context clearly mentions that the LUMO energy level and the HOMO energy level mean the LUMO energy level and HOMO energy level of a dopant material with which the layer is doped, respectively.

Here, the HOMO energy level is obtained by measuring the voltage corresponding to a first peak at which electrons are discharged from a target material through cyclic voltammetry (CV) while comparing with a reference material whose HOMO energy level is known. For example, the HOMO energy level of a substance can be measured based on a substance whose oxidation potential and reduction potential are known.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30% by weight, based on a total weight of the first material in the doped layer. A “doped” layer can be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt %, or when the p-type material is present in an amount of less than 30 wt %, the layer is considered to be a “doped” layer.

Further, the term “undoped” refers to layers that are not “doped”. For example, a layer can be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

In this present disclosure, an electroluminescence (EL) spectrum can be calculated by multiplying (a) a photoluminescence (PL) spectrum, which applies the inherent characteristics of an emissive material such as a dopant material or a host material included in an organic emission layer, by (b) an outcoupling or emittance spectrum curve, which is determined by the structure and optical characteristics of an organic light-emitting element including the thicknesses of organic layers such as, for example, an electron transport layer.

Hereinafter, example embodiments of the present disclosure will be described in detail with reference to the accompanying drawings. In adding reference numerals to elements of each of the drawings, although the same elements are illustrated in other drawings, like reference numerals can refer to like elements. All the components of each display device/apparatus according to all embodiments of the present disclosure are operatively coupled and configured.

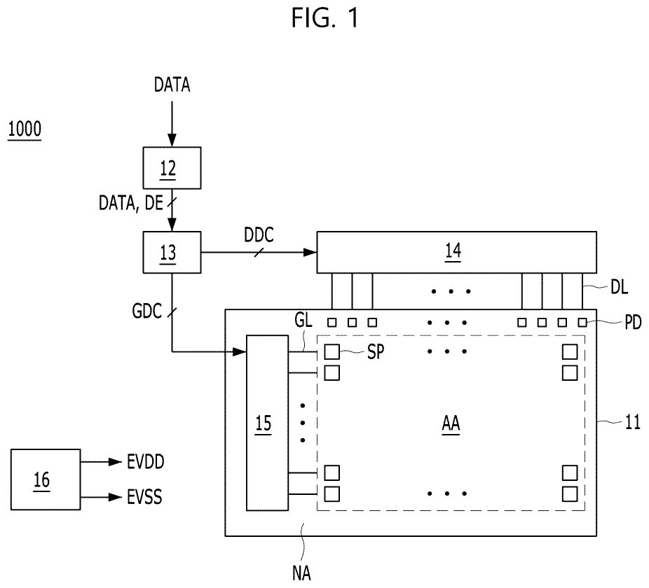

FIG. 1 is a block diagram schematically showing a light emitting display device according to an embodiment of the present disclosure.

As shown in FIG. 1, the light emitting display device 1000 according to the embodiment of the present disclosure can include a display panel 11, an image processing unit 12, a timing controller 13, a data driving unit 14, a scan driving unit 15, and a power supply unit 16.

The display panel 11 can display an image in response to a data signal DATA supplied from the data driving unit 14, a scan signal supplied from the scan driving unit 15, and power supplied from the power supply unit 16.

The display panel 11 can include subpixels SP disposed at intersections of a plurality of gate lines GL and a plurality of data lines DL. The structure of the subpixels SP can vary depending on the type of the light emitting display device 1000.

For example, the subpixels SP can be formed in a top emission, bottom emission, or dual emission manner depending on the structure thereof. A subpixel SP is a unit that can emit a specific color with or without a specific color filter. For example, the subpixels SP can include a red subpixel, a green subpixel, and a blue subpixel. Alternatively, the subpixels SP can include a red subpixel, a blue subpixel, a white subpixel, and a green subpixel. The subpixels SP can have one or more different emission areas based on their emission characteristics. For example, a blue subpixel and subpixels emitting different colors can have different emission areas.

One or more subpixels SP can constitute a unit pixel. For example, a unit pixel can include red, green, and blue subpixels, wherein the red, green, and blue subpixels can be repeatedly disposed. Alternatively, a unit pixel can include red, green, blue, and white subpixels, wherein the red, green, blue, and white subpixels can be repeatedly disposed or the red, green, blue, and white subpixels can be disposed in a Quad Bayer pattern. In the embodiment of the present disclosure, the color type, placement type, placement order, etc. of the subpixels can vary depending on the light emitting characteristics, the lifespan of the device, the specification of the display device, etc., but the present disclosure is not limited thereto.

The display panel 11 can be divided into an active area AA (in a dotted area) in which the subpixels SP are disposed to display an image and a non-active area NA around the active area AA. The scan driving unit 15 can be mounted at the non-active area NA of the display panel 11. The active area AA can be referred as a display area and the non-active area NA can be referred as a non-display area.

Further, the non-active area NA can include a pad unit PAD including a pad electrode PD.

Here, the active area AA can also be referred to as a display area and the non-active area NA can also be referred to as a non-display area.

The image processing unit 12 can output a data signal DATA supplied from the outside and a data enable signal DE. The image processing unit 12 can output one or more of a vertical synchronization signal, a horizontal synchronization signal, and a clock signal in addition to the data enable signal DE, but a description of these signals will be omitted for convenience.

The timing controller 13 can receive a driving signal and a data signal DATA from the image processing unit 12. The driving signal can include a data enable signal DE. Alternatively, the driving signal can include a vertical synchronization signal, a horizontal synchronization signal, and a clock signal. The timing controller 13 can output a data timing control signal DDC for controlling the operation timing of the data driving unit 14 and a gate timing control signal GDC for controlling the operation timing of the scan driving unit 15 based on the driving signal.

The data driving unit 14 can sample and latch the data signal DATA supplied from the timing controller 13 in response to the data timing control signal DDC supplied from the timing controller 13, convert the same into a gamma reference voltage, and output the same.

The data driving unit 14 can output the data signal DATA through the data lines DL. The data driving unit 14 can be implemented in the form of an integrated circuit (IC). For example, the data driving unit 14 can be electrically connected to the pad electrode PD disposed at the non-active area NA of the display panel 11 via a flexible circuit film.

The scan driving unit 15 can output a scan signal in response to a gate timing control signal GDC supplied from the timing controller 13. The scan driving unit 15 can output the scan signal via the gate lines GL. The scan driving unit 15 can be implemented in the form of an integrated circuit (IC) or can be implemented as a gate in panel GIP on the display panel 11.

The power supply unit 16 can output a high potential voltage and a low potential voltage to drive the display panel 11. The power supply unit 16 can supply the high potential voltage to the display panel 11 via a first power line EVDD (drive power line or pixel power line), and can supply the low potential voltage to the display panel 11 via a second power line EVSS (auxiliary power line or common power line).

The display panel 11 is divided into an active area AA and a non-active area NA, and can include a plurality of subpixels SP defined by gate lines GL and data lines DL that intersect and form a matrix at the active area AA.

The subpixels SP can include subpixels emitting at least two of red light, green light, blue light, yellow light, magenta light, and cyan light. Further, each of the plurality of subpixels SP can emit a specific color with or without specific color filters. However, the present disclosure is not necessarily limited thereto, and the color type, placement type, placement order, etc. of the subpixels SP can vary depending on the light emitting characteristics, the lifespan of the device, the specification of the display device, etc.

Each of the subpixels SP can include a light emitting portion and a non-light emitting portion surrounding the light emitting portion.

Hereinafter, a light emitting display device having light emitting portions REM, GEM, and BEM emitting colors corresponding to a red subpixel RSP, a green subpixel GSP, and a blue subpixel BSP according to an embodiment of the present disclosure will be described with reference to the drawings.

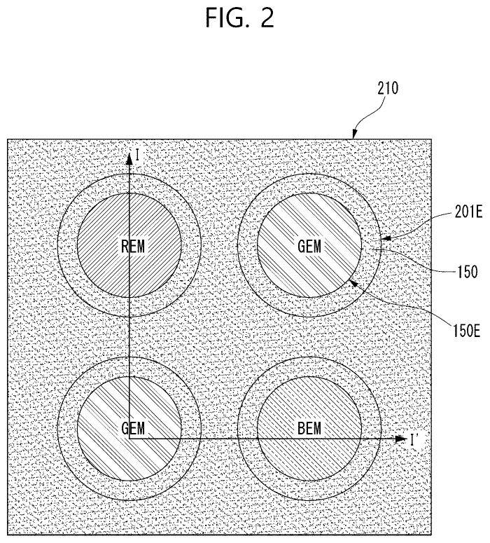

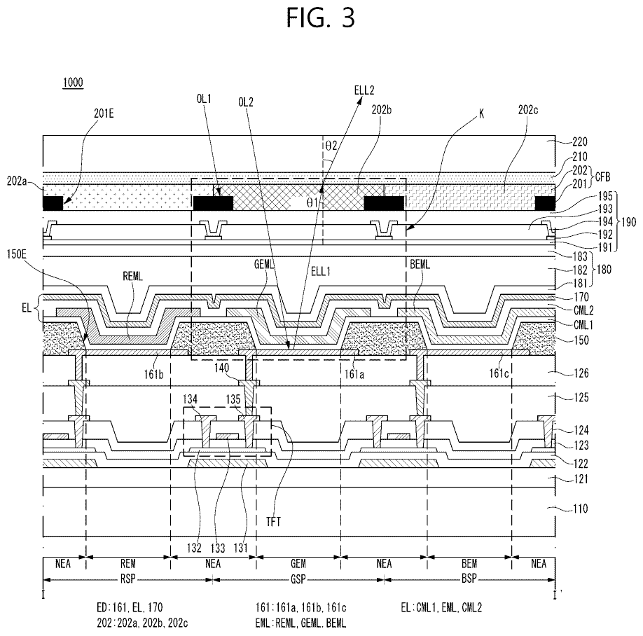

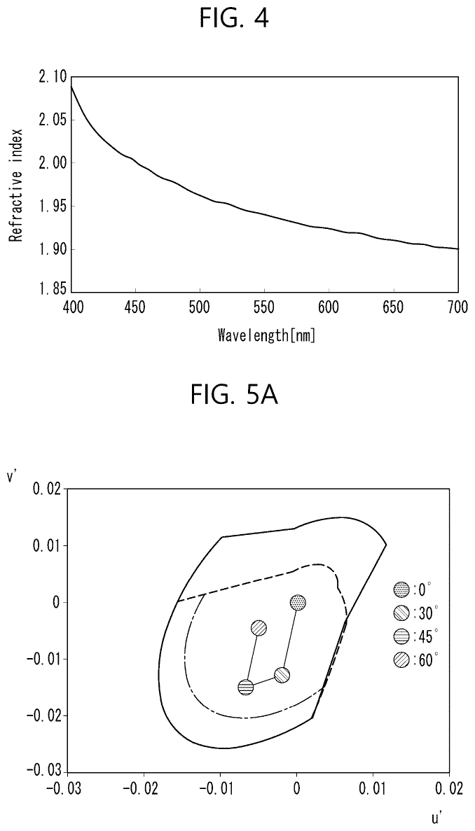

FIG. 2 is a plan view showing a light emitting display device according to a first embodiment of the present disclosure, and FIG. 3 is a sectional view taken along line I-I′ of FIG. 2. FIG. 4 is a graph showing the refractive index by wavelength of a refractive reinforcement layer of an embodiment of the present disclosure.

As shown in FIGS. 2 and 3, the light emitting display device 1000 according to the first embodiment of the present disclosure can include a substrate 110 having a plurality of subpixels RSP, GSP, and BSP, a transistor TFT, a light emitting device ED, an encapsulation layer 180, a touch sensor 190, an anti-reflective structure CFB, a refractive reinforcement layer 210, and an upper protective layer 220.

The substrate 110 can include at least one of a glass substrate, a plastic film, and a metal plate having certain supporting force. The substrate 110 can be made of a flexible material. For example, if the substrate 110 has multiple layers, the substrate 110 can have a structure in which a first organic layer, an inorganic insulating layer, and a second organic layer are stacked. The outermost first organic layer can prevent the introduction of external impurities. The second organic layer can enable surface planarization of a formation surface of an inner array structure and prevent charge transfer or impurity transfer from the outside to the inside. The inorganic insulating layer provided between the first and second organic layers can prevent moisture permeation diffusion between the first and second organic layers and the transfer of conductive impurities to the second organic layer.

The subpixels RSP, GSP, and BSP described herein refer to a plurality of partitioned areas disposed at the active area AA on the substrate 110. Each subpixel SP includes a light emitting portion REM, GEM, or BEM in the center and a non-light emitting portion NEM around the light emitting portion REM, GEM, or BEM.

The non-light emitting portion NEM is defined by a bank 150 that define the light emitting portions REM, GEM, and BEM of the subpixels. The bank 150 exposes the light emitting portions REM, GEM, and BEM of first electrodes 161a, 161b, and 161c disposed on the subpixels RSP, GSP, and BSP, and is disposed on the non-light emitting portion NEM. The bank 150 is disposed covering the edge of each of the first electrodes 161a, 161b, and 161c. The bank 150 is open to the light emitting portions REM, GEM, and BEM.

The bank 150 can include a light shielding organic material that absorbs or shields at least part of the visible spectrum, and can contribute to preventing exterior light visibility in conjunction with the anti-reflective structure CFB located thereon. The light shielding organic material of the bank 150 is a material that absorbs light, and includes an organic material that absorbs at least light in the visible spectrum. The bank 150 can include a material such as carbon black or a colored pigment. The bank 150 can also include a stack of a light shielding organic material layer and a transmitting organic material layer.

An end line 150E of the bank 150 is located at the boundary between the light emitting portions REM, GEM, and BEM and the non-light emitting portion NEM.

The light emitting display device 1000 can have a circuit configuration including a plurality of transistors TFT and one or more storage capacitors in each of the subpixels RSP, GSP, and BSP on the substrate 110, and can be selectively driven for each subpixel. In an example, FIG. 3 shows one transistor TFT provided in each of the subpixels RSP, GSP, and BSP, but the subpixel can include two or more transistors as desired. A pixel circuit of each of the subpixels RSP, GSP, and BSP can include one or more switching transistors configured to control whether the subpixel SP is turned on or off and a driving transistor configured to supply driving current to the light emitting device ED.

The transistor TFT includes an active layer 132, a gate electrode 133 overlapping a part of the active layer 132, and first and second source drain electrodes 134 and second source drain electrodes 135 connected to the active layer 132 and spaced apart from each other. A light shielding pattern 131 configured to prevent the active layer 132 from being affected by light entering through the substrate 110 can be further provided under the transistor TFT. The light shielding pattern 131 is preferably formed so as to have an area equal to or greater than the channel area of the active layer 132. In some cases, the light shielding pattern 131 can be omitted.

A plurality of insulating layers 121, 122, 123, and 124, 125, and 126 can be provided on the substrate 110.

A first insulating layer 121 can function as a buffer layer or an active buffer layer. The buffer layer and the active buffer layer can function to prevent impurities from being transferred from a lower side of wiring included in an internal array and the active layer to an upper side and to support and protect an upper configuration. The first insulating layer 121 can have a plurality of layers.

A transistors TFT and a storage capacitor can be disposed on the first insulating layer 121 for each of the subpixels RSP, GSP, and BSP.

A light blocking layer (e.g., light shielding pattern 131) that prevents or reduces light from being transmitted to the active layer 132 of the thin film transistor TFT from the lower side can be provided on the first insulating layer 121.

A second insulating layer 122 can be disposed Between the light blocking layer (e.g., light shielding pattern 131) and the active layer 132 for insulation.

The thin-layer transistor TFT can be disposed in each of the plurality of subpixels on the second insulating layer 122. For example, the transistor TFT can include an active layer 132, a gate electrode 133 overlapping the active layer 132 with the third insulating layer 123 interposed therebetween, and a first source drain electrode 134 and a second source drain electrode 135 connected to both sides of the active layer 132.

In an example, the storage capacitor can include a first storage electrode and a second storage electrode overlapping each other. At least one of the first and second storage electrodes can be made of the same material as the active layer 132, and the other can include the same material as at least one of the gate electrode 133, the first and second source drain electrodes 134 and 135, and the light blocking layer (e.g., light shielding pattern 131).

A third insulating layer 123 provided between the active layer 132 and the gate electrode 133 can function as a gate insulating layer.

The active layer 132 can include, for example, a silicon-based or oxide semiconductor. The silicon-based semiconductor can include crystalline and/or amorphous silicon. The oxide semiconductor can include at least one of gallium oxide, tin oxide, zinc oxide, indium oxide, iron oxide, and indium-gallium-zinc oxide. In some cases, the oxide semiconductor layer can include a plurality of layers having different materials or different compositions of different materials. Each subpixel can include a plurality of thin-layer transistors, and the thin-layer transistors can be located on different layers. For example, each subpixel of the substrate 110 can include a plurality of thin-layer transistors having different active layers. For example, a first thin-layer transistor can have a silicon-based active layer and can be disposed closer to the substrate 110, and a second thin-layer transistor can be located higher than the first thin-layer transistor and can have an active layer made of an oxide semiconductor.

The active layer 132 can include a channel area overlapping the gate electrode 133 and a source/drain area connected to each of the first and second source drain electrodes 134 and 135.

The third insulating layer 123 can be selectively disposed on the channel area of the active layer 132, or can be provided on the entire surface of the substrate 110, excluding the area through which the first and second source drain electrodes 134 and 135 extend. The third insulating layer 123 can function to isolate the active layer 132 and the gate electrode 133 from each other. The third insulating layer 123 can be made of an inorganic insulating material, and can be, for example, a silicon oxide (SiOx) layer, a silicon nitride (SiNx) layer, a silicon oxynitride (SiOxNy) layer, or a multilayer layer thereof.

A gate electrode 133 can be formed on the third insulating layer 123. The gate electrode 133 can be disposed so to face the active layer 132 with the third insulating layer 123 interposed therebetween.

A fourth insulating layer 124 that covers the gate electrode 133 and protects the gate electrode 133 can be formed on the gate electrode 133. Further, the fourth insulating layer 124 can function to protect at least one electrode of the thin-layer transistor TFT, such as the gate electrode 133, and the active layer 132. The fourth insulating layer 124 can be made of an inorganic insulating material. For example, the fourth insulating layer 124 can be a silicon oxide (SiOx) layer, a silicon nitride (SiNx) layer, a silicon oxynitride (SiOxNy) layer, or a multilayer layer thereof.

A first source drain electrode 114 and a second source drain electrode 115 can be disposed on the fourth insulating layer 124. The fourth insulating layer 124 and the third insulating layer 123 can have contact holes at both ends of the active layer 132 for contacting the first and second source drain electrodes 134 and 135, respectively, and therefore the areas can be removed.

Each of the gate electrode 133 and the first and second source drain electrodes 134 and 135 can have a single-layer structure or a multilayer structure.

If each of the gate electrode 133 and the first and second source drain electrodes 134 and 135 has a single-layer structure, each of the gate electrode 133 and the first and second source drain electrodes 134 and 135 can be made of any one selected from the group consisting of molybdenum (Mo), aluminum (Al), chromium (Cr), gold (Au), titanium (Ti), nickel (Ni), neodymium (Nd), and copper (Cu) or an alloy thereof. In addition, if each of the gate electrode 133 and the first and second source drain electrodes 134 and 135 has a multilayer structure, each of the gate electrode 133 and the first and second source drain electrodes 134 and 135 can have a dual layer of molybdenum/aluminum-neodymium, molybdenum/aluminum, titanium/aluminum, or copper/molytitanium. Alternatively, each of the gate electrode 133 and the first and second source drain electrodes 134 and 135 can have a triple layer of molybdenum/aluminum-neodymium/molybdenum, molybdenum/aluminum/molybdenum, titanium/aluminum/titanium, or molybdenum/copper/molybdenum.

However, the present disclosure is not limited thereto, and each of the gate electrode 133 and the first and second source electrodes 134 and 135 can be made of any one selected from the group consisting of molybdenum (Mo), aluminum (Al), chromium (Cr), gold (Au), titanium (Ti), nickel (Ni), neodymium (Nd), and copper (Cu) or an alloy thereof.

Each of the first to fourth insulating layers 121, 122, 123, and 124 can be made of an inorganic insulating layer. The inorganic insulating layer can be at least one of, for example, a silicon oxide layer, a silicon nitride layer, and a silicon oxynitride layer.

A first planarization layer 125 and a second planarization layer 126 can be provided on the first to fourth insulating layers 121, 122, 123, and 124. The first planarization layer 125 can be provided with a contact hole, and a connection electrode 140 connected to the second source drain electrode 135 can be provided in the contact hole. The second planarization layer 126 is disposed covering the connection electrode 140 and the first planarization layer 125. The first and second planarization layers 125 and 126 can each include an organic material. The organic material can include at least one of an acrylic resin, a phenolic resin, a polyimide resin, an unsaturated polyester resin, a polyamide resin, or a polyesters resin, benzocyclobutene, a polyphenylene resin, and a polyphenylene sulfide resin.

The connection electrode 140 can be made of any one selected from the group consisting of, for example, molybdenum (Mo), aluminum (Al), chromium (Cr), gold (Au), titanium (Ti), nickel (Ni), neodymium (Nd), and copper (Cu) or an alloy thereof.

The second source drain electrode 135 can be coupled to the connection electrode 140, and the connection electrode 140 can be connected to a first electrode 161 (161a, 161b, or 161c) of the light emitting device ED.

However, the present disclosure is not limited thereto. In some cases, the connection electrode 140 can be omitted. If the connection electrode 140 is omitted, one of the first and second source drain electrodes 134 and 135 can be directly connected to the first electrode 161 (161a, 161b, or 161c) of the light emitting device ED.

The light emitting device ED includes a stack of a first electrode 161a, 161b, or 161c, an intermediate layer EL, and a second electrode 170.

The light emitting display device 1000 emits light upward, wherein the first electrode 161a, 161b, or 161c of the light emitting device ED includes a reflective electrode, and the second electrode 170 includes a transflective electrode or a transmissive electrode.

The first electrode 161a, 161b, or 161c can include a highly reflective metal material. For example, the first electrode 161a, 161b, or 161c can be formed in a multilayer structure, such as a stack structure of aluminum (Al) and titanium (Ti) (Ti/Al/Ti), a stack structure of aluminum (Al) and ITO (ITO/Al/ITO), an APC (Ag/Pd/Cu) alloy, and a stack structure of an APC alloy and ITO (ITO/APC/ITO), or a stack structure of silver (Ag) and a molybdenum/titanium alloy (Ag/MoTI), or can include a monolayer structure made of any one selected from silver (Ag), aluminum (Al), molybdenum (Mo), gold (Au), magnesium (Mg), calcium (Ca), and barium (Ba) or an alloy of two or more. The first electrode 161a, 161b, or 161c can be referred to as a reflective electrode.

The second electrode 170 can be a light transmissive electrode. The second electrode 170 can include a transparent conductive material (TCO), such as indium tin oxide (ITO) or indium zinc oxide (IZO), or a semi-transmissive conductive material such as magnesium (Mg), silver (Ag), or an alloy of magnesium (Mg) and silver (Ag). If the second electrode 170 includes a semi-transmissive conductive material, light emission efficiency can be increased by the microcavity effect. If the second electrode 170 includes a semi-transmissive conductive material, the thickness of the second electrode 170 is small enough to allow light to pass therethrough. Furthermore, the thickness of the second electrode 170 can be such that the light generated in the intermediate layer EL can repeat the resonance between the first and second electrodes 161 and 170 and be emitted with microcavity characteristics.

The first electrodes 161a, 161b, and 161c are disposed in subpixels GSP, RSP, and BSP so as to be spaced apart from each other. The first electrode 161a, 161b, or 161c is disposed with an area larger than the light emitting portion GEM, REM, or BEM of each subpixel GSP, RSP, or BSP, and the edge of the first electrode 161a, 161b, or 161c is covered by the bank 150. The upper surface of the first electrode 161a, 161b, or 161c can abut the bank 150 or be in contact with the bank 150. The bank 150 disposed between adjacent subpixels can be disposed overlapping the edges of the first electrodes spaced apart from each other at the adjacent subpixels and the area between the first electrodes.

The intermediate layer EL can include a first common layer CML1, a light emitting layer REML, GEML, or BEML, and a second common layer CML2.

The first common layer CML1 disposed under the light emitting layer REML, GEML, or BEML can be, for example, a hole transport common layer. The first common layer CML1 can include a hole injection layer, a hole transport layer, an electron blocking layer.

The second common layer CML2 disposed above the light emitting layer REML, GEML, or BEML can be, for example, an electron transport common layer. The second common layer CML2 can include a hole blocking layer, an electron transport layer, and an electron injection layer.

In the example shown, the light emitting layers REML, GEML, and BEML are provided at the subpixels RSP, GSP, and BSP so as to be spaced apart from each other. In the light emitting device ED, the red, green, and blue subpixels RSP, GSP, and BSP emit red light, green light, and blue light, respectively, and red, green, and blue color filters 202a, 202b, and 202c of the anti-reflective structure CFB allow the red light, the green light, and the blue light to pass therethrough to clearly transmit light of a predetermined wavelength from the light emitting device ED at a narrower wavelength and improve color-specific reproducibility.

The present disclosure is not limited thereto. For example, the intermediate layers EL of the light emitting devices ED of the red subpixel RSP, the green subpixel GSP, and the blue subpixel BSP can have the same stack configuration. In this case, the interlayer EL can include one or more stacks, and a charge generation layer can be provided between neighboring stacks. Each stack can include one or more light emitting layers, and can include a first common layer CML1 under the light emitting layer and a second common layer CML2 above the light emitting layer. The charge generation layer can include a stack of an n-type charge generation layer and a p-type charge generation layer. When the intermediate layer EL includes a plurality of stacks and one or more charge generation layers, one of the plurality of stacks can include a blue light emitting layer, and the other stacks can include light emitting layers with a wavelength longer than blue. The light emitting layer in each stack can have a single layer or multiple layers.

In some cases, the intermediate layer EL can have a tandem configuration including a plurality of stacks and one or more charge generation layers in each of the subpixels RSP, GSP, and BSP, but can include separate light emitting layers. In this case, the red subpixel can have a red light emitting layer in each stack, the green subpixel can have a green light emitting layer in each stack, and the blue subpixel can have a blue light emitting layer in each stack.

The first electrode 161 (161a, 161b, and 161c) can comprise a reflective electrode. The first electrode 161 (161a, 161b, and 161c) prevents light generated in the intermediate layer EL from being transmitted to a light shielding component under the first electrode 161 (161a, 161b, or 161c). The light generated in the intermediate layer EL can resonate between the second electrode 170 and the first electrode 161 (161a, 161b, or 161c), and is finally emitted upward through the second electrode 170. Since the first electrode 161 (161a, 161b, or 161c) includes a reflective component, light from the light emitting device ED can be seen in the light emitting portion REM, GEM, or BEM even when overlapping wiring and the transistor TFT without affecting their placement.

The light emitting display device according to the embodiment of the present disclosure is a top emission type light emitting display device. In this case, the first electrode 161 (161a, 161b, or 161c) includes a reflective electrode, and the light generated in the intermediate layer EL resonates between the first electrode 161 (161a, 161b, or 161c) and the second electrode 170 through reflection and re-reflection, and is finally emitted toward the second electrode 170.

Meanwhile, green has the best visibility and provides the greatest contribution to luminance during white representation. Therefore, as shown in FIG. 2, the placement density of the green light emitting portion GEM can be greater than the placement density of the red light emitting portion REM and the blue light emitting portion BEM at the active area of the substrate 110. However, the present disclosure is not limited thereto.

An encapsulation layer 180 configured to protect the light emitting device ED is provided on the light emitting device ED.

The encapsulation layer 180 can include, for example, one or more inorganic encapsulation layers 181 and 183 and an organic encapsulation layer 182 alternately disposed.

A touch sensor 190 for sensing touch can be further provided on the encapsulation layer 180.

The touch sensor 190 can include a first touch electrode layer 192 and a second touch electrode layer 194.

The touch sensor 190 can be disposed on the encapsulation layer 180 at the active area AA to sense touch input. The touch sensor can detect external touch information using a user's finger or a touch pen. The touch sensor 190 can include a touch buffer layer 191, a first touch electrode layer 192, a touch intermediate insulating layer 193, a second touch electrode layer 194, and a touch protective layer 195.

Each of the touch buffer layer 191 and the touch intermediate insulating layer 193 can be made of an inorganic material, such as silicon nitride (SiNx), silicon oxide (SiOx), or silicon oxynitride (SiONx), but the present disclosure is not limited thereto.

In the touch sensor 190, the first touch electrode layer 192 and the second touch electrode layer 194, which are located on different layers, can be connected to each other and used as a first touch electrode Tx. A second touch electrode Rx can be provided on the second touch electrode layer 194 in an electrically separated state.

A touch sensing signal can be applied through one of the first touch electrode Tx and the second touch electrode Rx, and a change in response to touch can be sensed through the other.

The first and second touch electrode layers 192 and 194 of the touch sensor 190 can be disposed overlapping the bank 150 to prevent or reduce external visibility.

The first and second touch electrode layers 192 and 194 can each be made of a metal material. The present disclosure is not limited thereto.

In a light emitting display device 1000 according to another embodiment of the present disclosure, the touch sensor 190 can be omitted.

In the light emitting display device according to the embodiment of the present disclosure, a refractive reinforcement layer 210 is provided on the anti-reflective structure CFB.

The anti-reflective structure CFB includes a light shielding layer 201 and a color filter 202. The anti-reflective structure CFB can absorb external light to prevent or reduce the external light from being re-reflected in the configuration of the light emitting device ED when the external light enters the light emitting display device 1000 from above.

In the configuration of the anti-reflective structure CFB, the light shielding layer 201 can absorb or shield all visible light. The light shielding layer 201 can prevent or reduce outer light OL1 entering from the outside of the light emitting display device 1000 from passing through the light shielding layer 201. In addition, the light shielding layer 201 can prevent or reduce light emitted upward from the light emitting device ED at each of the subpixels RSP, GSP, and BSP from being diverted to a subpixel adjacent thereto.

As shown in FIGS. 2 and 3, the light shielding layer 201 can be disposed within the width of the bank 150 so as to have a width less than the width of the bank 150. Thus, for each of the light emitting portions REM, GEM, and BEM, the end line 201E of the light shielding layer 201 can be located farther outward than the end line 150E of the bank 150. In the light emitting display device according to the embodiment of the present disclosure, the refractive reinforcement layer 210 can be disposed at least between the end line 201E of the light shielding layer 201 and the end line 150E of the bank 150 to improve the luminance viewing angle due to the effect of refraction in a wider direction at the interface of the color filter 202 and the refractive reinforcement layer 210.

In the configuration of the anti-reflective structure CFB, the color filter 202 can transmit a predetermined wavelength of light in the visible spectrum and absorb or shield the remaining wavelengths of light.

As shown in FIG. 3, external light OL2 directed to the color filter 202 (202a, 202b, or 202c) passes through the color filter 202 (202a, 202b, or 202c), whereby light in the remaining wavelength bands except for the wavelength bands for which each color filter has transmittance is absorbed, and light in the wavelength bands for which each color filter has transmittance can be transmitted to the touch sensor 190, the encapsulation layer 180, and the light emitting device ED. When the external light OL2 is transmitted through the color filter 202 (202a, 202b, or 202c), the amount of light is limited, whereby the reflection effect of the external light over the light emitting device ED is small.

The color filter 202 can include a red color filter 202a at the red subpixel RSP, a green color filter 202b at the green subpixel GSP, and a blue color filter 202c at the blue subpixel BSP.

The red color filter 202a can transmit light of a red wavelength and absorb or block light of other wavelengths. The green color filter 202b can transmit light of a green wavelength and absorb or block light of other wavelengths. The blue color filter 202c can transmit light of a blue wavelength and absorb or block light of other wavelengths.

The color filter 202 is included in the anti-reflective structure CFB to prevent or reduce visibility of external light while enabling a clear color display of the light from the light emitting device ED of each of the subpixels RSP, GSP, and BSP.

The light emitting display device 1000 according to the embodiment of the present disclosure prevents or reduces the visibility of external light reflection through appropriately disposing the light shielding layer 201 and the color filter 202 in the anti-reflective structure. Light transmittance of the light emitting display device 1000 can be improved relative to the structure having a polarizer that blocks external light through a dichroic light absorbing material included in the polarizer. Thus, the light emitting display device 1000 can reduce power consumption compared to the structure using the polarizer when achieving the same luminance.

The light shielding layer 201 can be disposed at the non-light emitting portion NEM, and the color filter 202 (202a, 202b, or 202c) can be disposed at at least a corresponding one of the light emitting portions REM, GEM, and BEM.

The light shielding layer 201 is located within an area less than the area of the bank 150, whereby a part of the light directed slantly and upward from each of the subpixels RSP, GSP, BSP can be emitted through a gap between the light shielding layer 201 and the bank 150 to secure a certain luminance viewing angle or more even when the viewing angle changes.

The color filter 202 (202a, 202b, and 202c) covers the upper surface of the light shielding layer 201 and is disposed such that color filters of adjacent subpixels abut each other, whereby, when light from the light emitting device ED passes through the anti-reflective structure CFB, the light can pass through the color filter 202 (202a, 202b, or 202c). Thus, a lower surface of the refractive reinforcement layer 210 can abut or be in contact with the upper surface of the color filter 202 (202a, 202b, or 202c).

The color filter 202 (202a, 202b, or 202c) can be laterally adjacent to each other in adjacent subpixels, as shown in FIG. 2, or the color filter 202a, 202b, or 202c of a given subpixel can overlap the area where the light shielding layer 201 is disposed, and the color filter 202a, 202b, or 202c of another subpixel can be disposed covering the adjacent color filter 202a, 202b, or 202c.

The light shielding layer 201 is disposed over a smaller area of the non-light emitting portion NEM than the bank 150 and is disposed with a thickness less than the thickness of the color filter 202 (202a, 202b, or 202c). The upper surface and the side surface of the light shielding layer 201 can be covered by the color filters 202a, 202b, and 202c disposed at the subpixels RSP, GSP, and BSP.

As shown in FIGS. 2 and 3, the end line 201E of the light shielding layer 201 is placed on the bank 150.

The refractive reinforcement layer 210 is located on the anti-reflective structure CFB. When light ELL1 generated by the light emitting device ED proceeds from the upper surface of the anti-reflective structure CFB to the refractive reinforcement layer 210, the light encounters the interface between the upper surface of the anti-reflective structure CFB and the lower surface of the refractive reinforcement layer 210, and is refracted and emitted as light ELL2 having an angle of emission θ2 greater than the angle of incidence θ1 with respect to the normal direction of the interface of the anti-reflective structure CFB and the refractive reinforcement layer 210. In this case, the light generated by the light emitting device ED is finally emitted with a wider spread at the interface of the anti-reflective structure CFB and the refractive reinforcement layer 210. Thus, the viewing angle luminance can be secured when a viewer looking at the light emitting display device 1000 from the outside tilts his/her body at a certain angle from the front and looks at the same at a certain angle of view.

The refractive reinforcement layer 210 is made of a transparent organic thin layer. The refractive reinforcement layer 210 has a high refractive index of 1.90 or more in a wavelength band of 400 nm to 700 nm, as shown in FIG. 4.

In the light emitting display device according to the embodiment of the present disclosure, the red subpixel RSP emits red light having a light emission peak at a wavelength of 600 nm to 650 nm, the green subpixel GSP emits green light having a light emission peak at a wavelength of 500 nm to 590 nm, and the blue subpixel BSP emits blue light having a light emission peak at a wavelength of 440 nm to 490 nm.

Since the refractive reinforcement layer 210 has a high refractive index of 1.90 or more at 400 nm to 700 nm, which includes visible light wavelengths, as shown in FIG. 4, when the light emitted by the light emitting device ED passes through the refractive reinforcement layer 210, the light can be emitted in a wider range over the entire visible spectrum compared to a structure having no refractive reinforcement layer, thereby improving the viewing angle luminance.

The refractive reinforcement layer 210 can be made of a transparent organic thin film. The refractive reinforcement layer 210 has a higher refractive index than the color filter 202 (202a, 202b, or 202c) constituting the interface. Therefore, in the direction of light propagation, light from the color filter 202 of the anti-reflective structure CFB, which is a medium of low refractive index, passes through the refractive reinforcement layer 210, which is a medium of high refractive index, and proceeds with a wider angle of emission than the angle of incidence with respect to the interface normal at the interface of the color filter 202 and the refractive reinforcement layer 210 than the direction of light passing through the color filter 202.

Compared to the refractive reinforcement layer 210, the color filter 202 (202a, 202b, or 202c) of the anti-reflective structure CFB has a refractive index difference of 0.1 or more. The color filter 202 (202a, 202b, or 202c) includes colored pigment and can have a refractive index of approximately 1.6 to 1.8.

The refractive index difference causes light to be refracted as the light passes from a lower refractive index medium to a higher refractive index medium, thereby expanding the emission range of the light, which can improve luminance as the viewing angle changes.

In the path of incident light, light proceeding from the refractive reinforcement layer 210 to the anti-reflective structure CFB can proceed without refraction when passing from a high refractive index medium to a low refractive index medium.

The refractive reinforcement layer 210 is formed, for example, by vaporizing elemental sulfur and polymerizing the vaporized sulfur with various materials to form a transparent high refractive index polymeric layer. The refractive reinforcement layer 210 is formed without having excessively long sulfur-sulfur chains in the internal chemical bonding structure thereof, even if the overall sulfur content is large, and without significantly increasing its thickness by bonding sulfur atoms with other atoms, including carbon, etc. The refractive reinforcement layer 210 has excellent permeability because the refractive reinforcement layer does not have an internal crystalline phase, and can comprise a thin layer along the upper surface of the anti-reflective structure CFB by reducing the length of the bond chains.

In the light emitting display device according to the first embodiment, the refractive reinforcement layer 210 is provided on the entire anti-reflective structure CFB. However, the present disclosure is not limited thereto. The patterned configuration of the refractive reinforcement layer 210 will be described later when describing other embodiments of the present disclosure.

In the area where the refractive reinforcement layer 210 and the light shielding layer 201 overlap each other, light in the visible spectrum is absorbed through the light shielding layer 201, whereby, even if the refractive reinforcement layer 210 is provided on the entire anti-reflective structure CFB, the luminance viewing angle is improved by bending the light path at the interface of the color filter 202 (202a, 202b, or 202c) not overlapping the light shielding layer 201 and the refractive reinforcement layer 210 in a wider direction from the direction of travel.

On the refractive reinforcement layer 210, an upper protective layer 220 is disposed to protect the lower configuration from external physical impact. The upper protective layer 220 is made of glass or an organic layer and has a protective function.

Here, an adhesive layer can further be provided between the refractive reinforcement layer 210 and the upper protective layer 220.

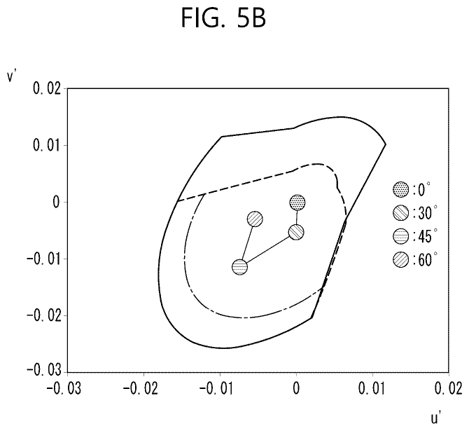

FIGS. 5A and 5B are graphs showing Au′v′ by viewing angle of first and second experimental examples.

The second experimental example EX2 has a refractive reinforcement layer 210, as in the light emitting display device according to the first embodiment, and the first experimental example EX1 has a structure in which the refractive reinforcement layer is omitted from the light emitting display device according to the first embodiment.

Table 1 shows white luminance, red luminance, green luminance, and blue luminance by viewing angle of the first experimental example EX1 compared to frontal luminance.

Table 2 shows white luminance, red luminance, green luminance, and blue luminance by viewing angle of the second experimental example EX2 compared to frontal luminance.

TABLE 1

| Viewing | White | Red | Green | Blue |
|---|---|---|---|---|
| angle | luminance | luminance | luminance | luminance |
| (°) | (%) | (%) | (%) | (%) |
| 0 | 100 | 100 | 100 | 100 |
| 30 | 74.6 | 81.7 | 72.6 | 63.8 |
| 45 | 36.1 | 38.1 | 36.0 | 28.2 |
| 60 | 17.4 | 18.4 | 17.4 | 12.5 |

TABLE 2

| Viewing | White | Red | Green | Blue |
|---|---|---|---|---|
| angle | luminance | luminance | luminance | luminance |
| (°) | (%) | (%) | (%) | (%) |
| 0 | 100 | 100 | 100 | 100 |
| 30 | 84.3 | 98.8 | 81.2 | 65.3 |
| 45 | 42.9 | 47.1 | 42.3 | 30.8 |
| 60 | 20.4 | 22.6 | 20.1 | 13.6 |

Referring to Table 1 and Table 2, it can be seen that the white luminance increases with the change of viewing angle in the second experimental example EX2 compared to the first experimental example EX1. In particular, at a viewing angle of 30°, there is a 9.7% increase in luminance in the second experimental example EX2 compared to the first experimental example EX1, at a viewing angle of 45°, there is a 6.8% increase in luminance in the second experimental example EX2 compared to the first experimental example EX1, and at a viewing angle of 60°, there is a 3.0% increase in luminance in the second experimental example EX2 compared to the first experimental example EX1.

It can be seen that not only the white luminance, but also the red luminance, the green luminance, and the blue luminance are improved in the second experimental example EX2 compared to the first experimental example EX1 at different viewing angles.

In recent years, light emitting display devices have become larger and have been configured to be viewed by a plurality of viewers with various viewing angles, and therefore there is a need to reduce luminance degradation at a change in viewing angle.

The comparison of the luminance by viewing angle of the first and second experimental examples EX1 and EX2 shows that the luminance viewing angle is improved in change of viewing angle when the high refractive index refractive reinforcement layer is provided on the anti-reflective structure and that the luminance viewing angle requirement of the luminance viewing angle above a certain level of the change of viewing angle is satisfied.

FIGS. 5A and 5B show the color coordinate fluctuations of white compared to the frontal state in the first experimental example EX1 and the second experimental example EX2 at each viewing angle.

Referring to FIGS. 5A and 5B, it can be seen that, when the viewing angle is changed from front (0°) to 30°, 45°, and 60° in the second experimental example EX2, the color coordinate variation is smaller at each viewing angle compared to front than in the first experimental example EX1.

Also, it can be seen that the color coordinate variation of the second experimental example EX2 is much less than the color coordinate variation of the first experimental example EX1 at the variation of a viewing angle of 30° from the front (0°), which is mainly prevalent in the use environment. Therefore, it can be expected that the structure of the light emitting display device according to the present disclosure having the refractive reinforcement layer applied thereto has smaller luminance degradation at a change in viewing angle than a structure having no refractive reinforcement layer, which is advantageous for wide viewing angle realization.

Meanwhile, it can be seen from the results of Table 1 and Table 2 that the white luminance tends to be almost the same as the green luminance. That is, in the light emitting display device, the white luminance is dominantly affected by the green luminance.

Therefore, even if the green subpixel is selectively provided with a refractive reinforcement layer, it is possible to achieve the same effect of improving the white luminance efficiency as the viewing angle changes.

Hereinafter, embodiments in which a refractive reinforcement layer is selectively provided at the green subpixel GSP that selectively emits a green color will be described.

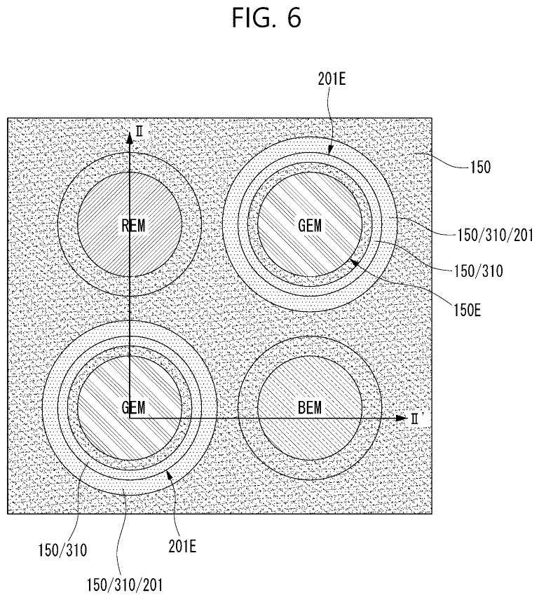

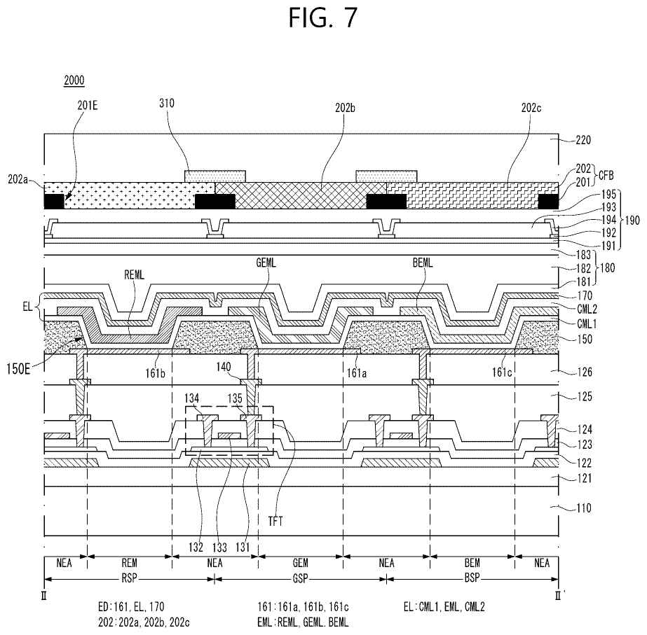

FIG. 6 is a plan view showing a light emitting display device according to a second embodiment of the present disclosure, and FIG. 7 is a sectional view taken along line II-II′ of FIG. 6.

As shown in FIGS. 6 and 7, in the light emitting display device 2000 according to the second embodiment of the present disclosure, a refractive reinforcement layer 310 and a light shielding layer 201 are provided so as to overlap each other.

An end line 201E of the light shielding layer 201 is placed on the bank 150, and the refractive reinforcement layer 310 overlaps the end line 201E of the light shielding layer 201 and extends to the outside of the light shielding layer 201.

The width of the refractive reinforcement layer 310 is less than the width of the bank 150, but the refractive reinforcement layer 310 covers the entirety of the light shielding layer 201 and extends farther outwardly of the light shielding layer 201. Here, the refractive reinforcement layer 310 overlaps a non-light emitting portion NEM. At the position of the refractive reinforcement layer 310 spaced apart from the light shielding layer 201, the luminance enhancement effect by interfacial refraction can be obtained.

The refractive reinforcement layer 310 is a transparent polymer thin layer having a refractive index greater than the refractive index of a color filter 202a of an anti-reflective structure CFB abutting a lower part thereof.

The refractive reinforcement layer 310 is disposed at the non-light emitting portion NEM such that the light proceeding radially from a light emitting device ED can be directed in such a way that the light becomes wider at the interface of the anti-reflective structure CFB and the refractive reinforcement layer 310, thereby increasing the luminance viewing angle. Accordingly, when the light emitting display device 2000 is observed in a direction in which the viewing angle is changed, the degree of perceived luminance degradation is small even when the viewing angle is different from the front.

In the light emitting display device 2000 according to the second embodiment of the present description, as shown in FIGS. 6 and 7, the refractive reinforcement layer 310 is selectively provided at the green subpixel GSP. In the green subpixel GSP, the luminance viewing angle enhancement due to a change in viewing angle can predominantly produce a luminance viewing angle enhancement effect on a white viewing angle change. However, the present disclosure is not limited thereto. Even in the red subpixel and/or the blue subpixel, it is possible to obtain a luminance viewing angle improvement with a change in the viewing angle of each subpixel and to obtain a visual perception enhancement effect by further providing a refractive reinforcement layer having a width less than the width of the bank 150 but covering the entirety of the light shielding layer 201 and extending farther outwardly of the light shielding layer 201.

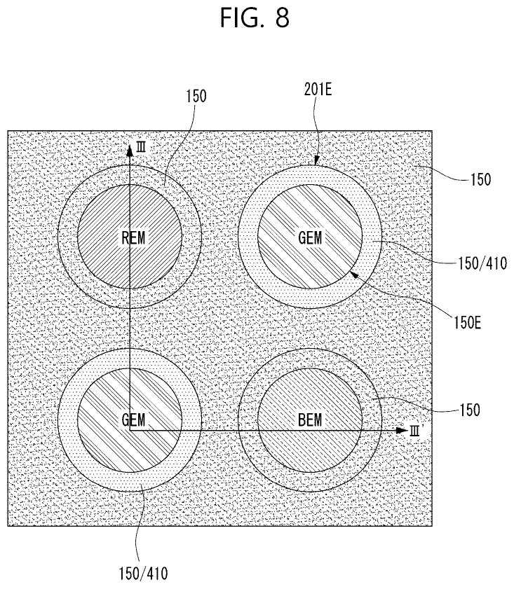

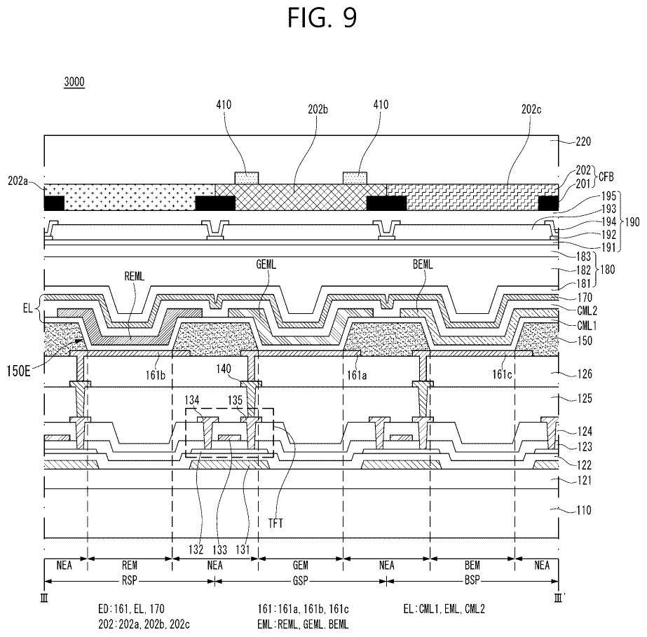

FIG. 8 is a plan view showing a light emitting display device according to a third embodiment of the present disclosure, and FIG. 9 is a sectional view taken along line III-III′ of FIG. 8.

As shown in FIGS. 8 and 9, in the light emitting display device 3000 according to the third embodiment of the present disclosure, a refractive reinforcement layer 410 can have a width less than the width of a bank 150 and can be disposed outside a light shielding layer 201 while not overlapping the light shielding layer 201. In this case, the refractive reinforcement layer 410 can be planarly aligned with an end line 201E of the light shielding layer 201 on a side surface thereof. Here, the refractive reinforcement layer 410 overlaps a non-light emitting portion NEM. At the position of the refractive reinforcement layer 410 spaced apart from the light shielding layer 201, the luminance enhancement effect by interfacial refraction can be obtained.

The refractive reinforcement layer 410 is a transparent polymer thin layer having a refractive index greater than the refractive index of a color filter 202a of an anti-reflective structure CFB abutting a lower part thereof.

The refractive reinforcement layer 410 is disposed at the non-light emitting portion NEM such that the light proceeding radially from a light emitting device ED can be directed in such a way that the light becomes wider at the interface of the anti-reflective structure CFB and the refractive reinforcement layer 410, thereby increasing the luminance viewing angle. Accordingly, when the light emitting display device 3000 is observed in a direction that the viewing angle is changed, the degree of luminance decrease compared to the front is small, and therefore the luminance viewing angle is improved.

In the light emitting display device 3000 according to the third embodiment, the width of the refractive reinforcement layer 410 can correspond to the width of the bank 150 minus the width of the light shielding layer 201.

The bank 150 can be made of a light shielding organic material, which prevents mixing between neighboring subpixels RSP, GSP, and BSP, and can assist the anti-reflective function of the anti-reflective structure CFB by shielding.

In the light emitting display device 3000 according to the third embodiment, the luminance viewing angle in the frontal direction can be maintained at the same level as a structure having no refractive reinforcement layer, and the luminance viewing angle at a change in viewing angle can be improved by the refractive reinforcement layer 410 provided outside the light shielding layer 201, thereby reducing the change in visual perception when the viewing angle changes.

In the light emitting display device 3000 according to the third embodiment of the present description, as shown in FIGS. 8 and 9, the refractive reinforcement layer 410 is selectively provided at the green subpixel GSP. In the green subpixel GSP, the luminance viewing angle enhancement due to a change in viewing angle can predominantly produce a luminance viewing angle enhancement effect on a white viewing angle change. However, the present disclosure is not limited thereto. Visual perception can be enhanced. Even in the red subpixel and/or the blue subpixel, it is possible to obtain a luminance viewing angle improvement with a change in the viewing angle of each subpixel by further providing a refractive reinforcement layer 410 having a width less than the width of the bank 150 but covering the entirety of the light shielding layer 201 and located outside the light shielding layer 201.

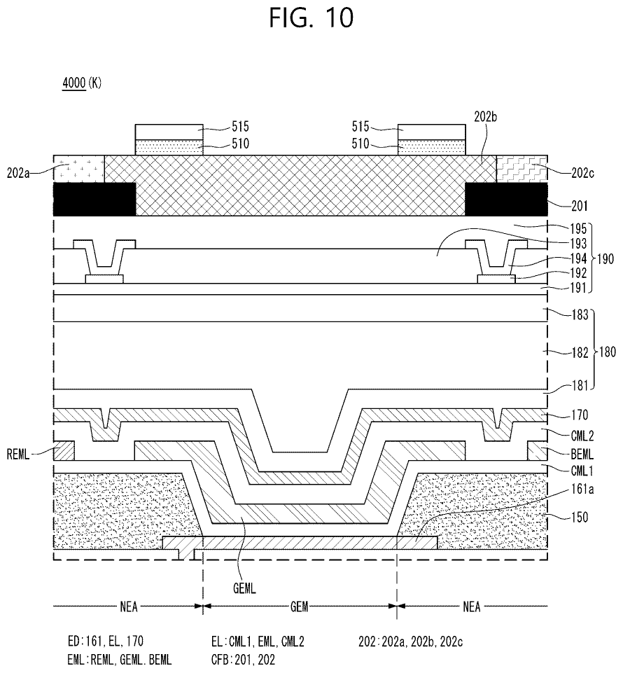

FIG. 10 is a sectional view showing a change of area K of FIG. 3 according to a fourth embodiment of the present disclosure.

As shown in FIG. 10, the light emitting display device 4000 according to the fourth embodiment of the present disclosure further includes, in addition to the structure of a refractive reinforcement layer 510 disposed on a color filter 202a, 202b, or 202c, a refractive adjustment layer 515 having a refractive index less than the refractive index of the refractive reinforcement layer 510.

The refractive reinforcement layer 510 is a transparent polymer thin layer having a refractive index greater than the refractive index of a color filter 202a of an anti-reflective structure CFB abutting a lower part thereof.

The refractive adjustment layer 515 can be, for example, a transparent organic material having a refractive index of 1.5 or less and a refractive index difference of about 0.4 or more from the refractive reinforcement layer 510. The refractive adjustment layer 515 can be made of a polymethyl methacrylate (PMMA)-based material, a polyvinyl alcohol (PVA)-based material, or a polyimide-based material. The refractive adjustment layer 515 has the effect of increasing the refractive angle on the final emission side when the refractive reinforcement layer 510 is stacked in a direction that is wider than in the above-described embodiments, and the effect of increasing the luminance viewing angle due to a change in the viewing angle is greater.

In the light emitting display device 4000 according to the fourth embodiment of the present description, the refractive reinforcement layer 510 can have a width less than the width of the bank 150, as shown, but can be disposed outside the light shielding layer 201 while not overlapping the light shielding layer 201. In addition, the refractive reinforcement layer 510 and the refractive adjustment layer 515 can have the same width and be patterned in a same process.

In this case, the refractive reinforcement layer 510 and the refractive adjustment layer 515 can be planarly aligned with the end line 201E of the light shielding layer 201 on a side surface thereof. Here, the refractive reinforcement layer 510 and refractive adjustment layer 515 overlap the non-light emitting portion NEM. In a stack structure of the refractive reinforcement layer 510 and the refractive adjustment layer 515 spaced apart from the light shielding layer 201, a luminance enhancement effect by interfacial refraction can be achieved.

In some cases, the refractive adjustment layer 515 can be integrally formed with an upper protective layer 220 (see FIG. 3) located at the uppermost end of the light emitting display device 4000. In this case, the refractive adjustment layer 515 can cover the upper surface and the side surface of the refractive reinforcement layer 510 and can be sized so as to correspond to the substrate 110.

In the light emitting display device according to the embodiment of the present disclosure, external light reflection can be prevented or reduced by disposing a light shielding layer and an anti-reflective structure CFB including a color filter, except for a polarizer that reduces or reduces the light transmittance, thereby preventing the light transmittance reduction that occurs when the polarizer is provided and improving the light transmittance.

In the light emitting display device according to the embodiment of the present disclosure, the polarizer can be omitted to increase the transmittance through a light emitting device, thereby reducing power consumption at a given luminance compared to a display device using a polarizer.

In the light emitting display device according to the embodiment of the present disclosure, a wide viewing angle can be applied by adding a refractive reinforcement layer in a configuration that radially widens the emitted light from the final emission side of the anti-reflective structure, thereby securing a certain or more luminance efficiency not only in the frontal direction but also when the viewing angle changes.

In the light emitting display device according to the embodiment of the present disclosure, visual perception can be improved by selectively adding a refractive reinforcement layer to a subpixel that emits a particular color that has a large luminance variation with a change in viewing angle and is particularly dominant in the luminance expression of white, thereby preventing or reducing color-specific luminance deviation with a change in viewing angle. In the light emitting display devices according to the embodiments of FIGS. 6 to 10, the refractive reinforcement layer is provided at the green subpixel, but the present disclosure is not limited thereto. The light emitting color dominant to the white luminance expression can change due to material changes in the light emitting device, and accordingly the refractive reinforcement layer can be optionally provided at the subpixel emitting the color dominant to the white luminance expression in addition to the green subpixel.

In the light emitting display device according to the embodiment of the present disclosure, the transmittance can be secured and driving voltage can be reduced by omitting the polarizer. In addition, it is possible to improve light emission efficiency by providing a refractive reinforcement layer and to improve visual perception by reducing a luminance deviation due to a change in a viewing angle. In the display device, therefore, continuous applicability is possible, whereby ESG (environmental/social/governance) goals can be achieved.

Meanwhile, in the section of the light emitting display device according to the embodiment, the red light emitting layer REML, the green light emitting layer GEML, and the blue light emitting layer BEML emitting different colors are independently disposed at the red subpixel RSP, the green subpixel GSP, and the blue subpixel BSP, respectively, but the present disclosure is not limited thereto.

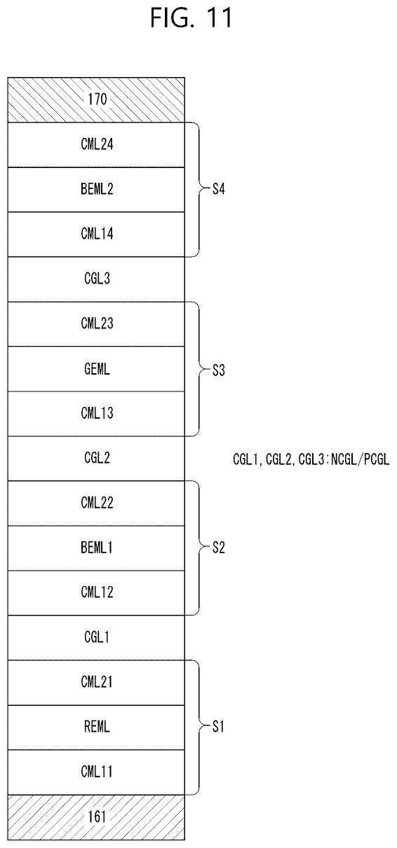

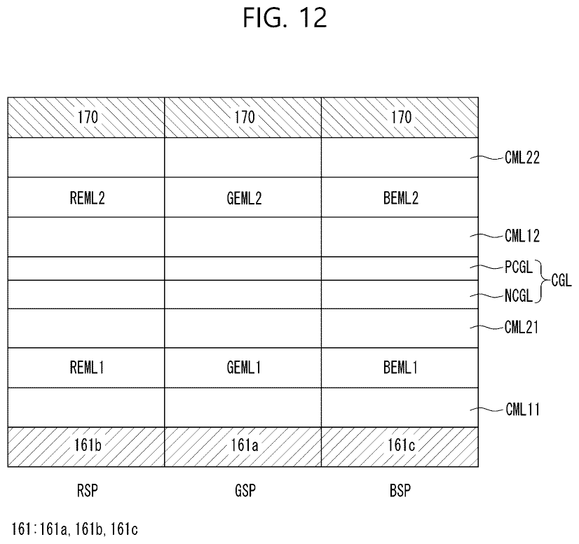

FIGS. 11 and 12 are sectional views showing other examples of the light emitting device of the light emitting display device according to the present disclosure.

In the light emitting device of FIG. 11, each of subpixels RSP, GSP, and BSP can include a first light emitting stack S1 as a red light emitting stack that emits red, a second light emitting stack S2 as a first blue light emitting stack that emits blue, a third light emitting stack S3 as a green light emitting stack that emits green, and a fourth light emitting stack S4 as a second blue light emitting stack that emits blue. That is, in FIG. 11, the light emitting device of each subpixel can express white color through placement of the R/B1/G/B2 light emitting stacks in a direction from a first electrode 161 to a second electrode 170. Even if the light emitting device of FIG. 11 is included equally in each subpixel, individual color expression of each of the subpixels RSP, GSP, and BSP is possible through a red color filter 202a, a green color filter 202b, and a blue color filter 202c disposed on an anti-reflective structure CFB.

The example of FIG. 11 illustrates an example having light emitting devices emitting white color as a plurality of stacks. However, the present disclosure is not limited thereto. For example, when the plurality of light emitting stacks is disposed between the first and second electrodes, the red light emitting stack, the green light emitting stack, and the first and second blue light emitting stacks can be disposed in that order (R/G/B1/B2) between the first and second electrodes, unlike the example shown in FIG. 11, which is disposed by color, the green light emitting stack, the red light emitting stack, and the first and second blue light emitting stacks can be disposed in that order (G/R/B1/B2), the first blue light emitting stack, the red light emitting stack, the green light emitting stack, and the second blue light emitting stack can be disposed in that order (B1/R/G/B2), or the stacks can be disposed in different orders.

Here, the reason that the two light emitting stacks that emit blue are disposed in the light emitting device is that it is necessary to compensate for the relatively low efficiency of blue compared to other colors.

The light emitting device including the first to fourth light emitting stacks S1, S2, S3, and S4 can emit white when certain voltage is applied between the first electrode 161 and the second electrode 170.

As shown in FIG. 12, a light emitting device according to another embodiment of the present disclosure can further include a first electrode 161 (161b, 161a, or 161c) opposite each of a red subpixel RSP, a green subpixel GSP, and a blue subpixel BSP, a second electrode 170, and a plurality of light emitting stacks provided between the first electrode 161 (161b, 161a, or 161c) and second electrode 170, wherein the plurality of light emitting stacks can have light emitting layers emitting the same color overlapping each other.

That is, the red subpixel RSP has red light emitting layers REML1 and REML2 in stacks divided by a charge generation layer CGL, the green subpixel GSP has green light emitting layers GEML1 and GEML2 in stacks divided by a charge generation layer CGL, and the blue subpixel BSP can have blue light emitting layers BEML1 and BEML2 in stacks separated by a charge generation layer CGL.

Here, a common layer CML11 related to hole injection and hole transport is provided between the first electrode 161 (161b, 161a, or 161c), the first red light emitting layer REML1, the first green light emitting layer GEML1, and the first blue light emitting layer BEML1, and a common layer CML21 related to electron transport is provided between the first red light emitting layer REML1, the first green light emitting layer GEML1, the first blue light emitting layer BEML1, and the charge generation layer CGL.

The charge generation layer CGL can include an n-type charge generation layer nCGL and a p-type charge generation layer pCGL, which are stacked.

Further, a common layer CML12 related to hole injection and hole transport can be provided between the charge generation layer CGL, the second red light emitting layer REML2, the second green light emitting layer GEML2, and the second blue light emitting layer BEML2, and a common layer CML22 including an electron transport layer and an electron injection layer can be provided between the second red light emitting layer REML2, the second green light emitting layer GEML2, the second blue light emitting layer BEML2, and the second electrode 170.

The common layers CML11 and CML12 related to hole injection and transport can include at least one of a hole injection layer, a hole transport layer, and an electron blocking layer, and the common layers CML21 and CML22 related to electron transport and injection can include at least one of a hole blocking layer, an electron transport layer, and an electron injection layer.

The light emitting device of FIG. 12 has a color-specific independent tandem structure in each of the red subpixel RSP, the green subpixel GSP, and the blue subpixel BSP. Another embodiment can further include a light emitting stack including a charge generation layer and independent red, green, and blue light emitting layers.

In the structure having the above-described light emitting device, the refractive reinforcement layer described with reference to FIGS. 2 to 10 can be further provided on the anti-reflective structure CFB such that light from the light emitting device is refracted more widely in a direction toward the emission side, thereby improving the luminance viewing angle when the viewing angle changes.

A light emitting display device according to one embodiment of the present disclosure can comprise a substrate comprising a plurality of subpixels, each having a light emitting portion and a non-light emitting portion, a bank configured to open the light emitting portion of each of the plurality of subpixels, the bank at the non-light emitting portion, a light emitting device at each of the plurality of subpixels, an encapsulation layer configured to cover the light emitting device, an anti-reflective structure comprising a light shielding layer located on the encapsulation layer while overlapping the non-light emitting portion and a color filter located on the encapsulation layer while overlapping the light emitting portion and a refractive reinforcement layer located on the anti-reflective structure while overlapping the color filter, the refractive reinforcement layer having a larger refractive index than the color filter.

In a light emitting display device according to one embodiment of the present disclosure, the refractive reinforcement layer can overlap the bank and does not overlap the light shielding layer.

In a light emitting display device according to one embodiment of the present disclosure, the light shielding layer can overlap a part of the bank, and the refractive reinforcement layer can be disposed between an end line of the light shielding layer and an end line of the bank on a plane.

In a light emitting display device according to one embodiment of the present disclosure, the light shielding layer can overlap a part of the bank, and the refractive reinforcing layer can overlap an entirety of the light shielding layer and overlaps the bank with an area equal to or less than an area of the bank.

In a light emitting display device according to one embodiment of the present disclosure, the refractive reinforcement layer can be disposed at a subpixel configured to emit a green color.

In a light emitting display device according to one embodiment of the present disclosure, the refractive reinforcement layer can abut an upper surface of the color filter.

In a light emitting display device according to one embodiment of the present disclosure, the bank can comprise a light shielding organic material. The light shielding layer can be provided on a part of the non-light emitting portion. The color filter can cover an upper surface of the light shielding layer and be disposed such that color filters of adjacent subpixels abut each other.

In a light emitting display device according to one embodiment of the present disclosure, the plurality of subpixels can comprise a first subpixel having a first light emitting portion configured to emit light of a first wavelength, a second subpixel having a second light emitting portion configured to emit light of a second wavelength shorter than the first wavelength, and a third subpixel having a third light emitting portion configured to emit light of a third wavelength longer than the first wavelength. The refractive reinforcement layer can be located outside the first light emitting portion while overlapping the first subpixel.

In a light emitting display device according to one embodiment of the present disclosure, the color filter can comprise a green color filter at the first subpixel, a blue color filter at the second subpixel, and a red color filter at the third subpixel. The refractive reinforcement layer can abut the green color filter.

A light emitting display device according to one embodiment of the present disclosure can further comprise a refractive adjustment layer on the refractive reinforcement layer, the refractive adjustment layer having a smaller refractive index than the refractive reinforcement layer.

In a light emitting display device according to one embodiment of the present disclosure, the refractive adjustment layer and the refractive reinforcement layer can have the same width.

In a light emitting display device according to one embodiment of the present disclosure, the color filter can comprise a green color filter at the first subpixel, a blue color filter at the second subpixel, and a red color filter at the third subpixel. The light emitting display device can further comprise a refractive adjustment layer overlapping the refractive reinforcement layer on the green color filter, the refractive adjustment layer having a smaller refractive index than the refractive reinforcement layer.

In a light emitting display device according to one embodiment of the present disclosure, the refractive reinforcement layer can have a refractive index of 1.9 or more in a visible light wavelength band.

A light emitting display device according to one embodiment of the present disclosure can comprise a substrate comprising a red subpixel, a green subpixel, and a blue subpixel, each having a light emitting portion and a non-light emitting portion, a bank configured to open the light emitting portion of each of the red subpixel, the green subpixel, and the blue subpixel, the bank at the non-light emitting portion, a light emitting device at each of the red subpixel, the green subpixel, and the blue subpixel, an encapsulation layer configured to cover the light emitting device, an anti-reflective structure on the encapsulation layer, the anti-reflective structure comprising a light shielding layer overlapping the non-light emitting portion, a red color filter overlapping the light emitting portion of the red subpixel, a green color filter overlapping the emitting portion of the green subpixel, and a blue color filter overlapping the emitting portion of the blue subpixel and a refractive reinforcement layer on the anti-reflective structure, the refractive reinforcement layer at least overlapping the green color filter and having a larger refractive index than the green color filter.

In a light emitting display device according to one embodiment of the present disclosure, the refractive reinforcement layer can abut an upper surface of each of the red color filter, the green color filter, and the blue color filter.

In a light emitting display device according to one embodiment of the present disclosure, the refractive reinforcement layer can overlap the bank and does not overlap the light shielding layer.

In a light emitting display device according to one embodiment of the present disclosure, the bank can comprise a light shielding organic material. The light shielding layer can be provided on a part of the non-light emitting portion. Each of the red color filter, the green color filter, and the blue color filter can cover an upper surface of the light shielding layer at the non-light emitting portion.

One side of the green color filter can abut the red color filter on the upper surface of the light shielding layer and the other side of the green color filter can abut the blue color filter on the upper surface of the light shielding layer.

A light emitting display device according to one embodiment of the present disclosure can further comprise a refractive adjustment layer between the green color filter and the refractive reinforcement layer, the refractive adjustment layer having a smaller refractive index than the refractive reinforcement layer.

In a light emitting display device according to one embodiment of the present disclosure, the refractive reinforcement layer may not overlap the light emitting portion of the green subpixel.

As is apparent from the above description, a light emitting display device according to aspects of the present disclosure has the following effects.

First, in the light emitting display device according to the embodiment of the present disclosure, external light reflection can be prevented or reduced by disposing a light shielding layer and a color filter, except for a polarizer that reduces the light transmittance, thereby preventing or reducing the light transmittance reduction that occurs when the polarizer is provided and improving the light transmittance.

Second, in the light emitting display device according to the embodiment of the present disclosure, the polarizer can be omitted. The polarizer reduces transmittance of the light emitting display device. In the light emitting display device, the polarizer are not provided, thus transmittance of the light emitting display device can be increased. Also the light emitting display device can reduce power consumption compared to a display device using a polarizer for the same luminance expression.

Third, in the light emitting display device according to the embodiment of the present disclosure, a wide viewing angle can be realized by adding a configuration that radially widens the emitted light from the final emission side of an anti-reflective structure, thereby securing a certain or more luminance efficiency not only in the frontal direction but also when the viewing angle changes.

Fourth, in the light emitting display device according to the embodiment of the present disclosure, visual perception can be improved by selectively adding a refractive reinforcement layer to a subpixel that emits a particular color that has a large luminance variation with a change in viewing angle, thereby preventing color-specific luminance deviation with a change in viewing angle.

Fifth, transmittance can be secured and driving voltage can be reduced by omitting the polarizer. In addition, it is possible to improve light emission efficiency by providing a refractive reinforcement layer and to improve visual perception by reducing a luminance deviation due to a change in a viewing angle. In the display device, therefore, continuous applicability is possible, whereby ESG (environmental/social/governance) goals can be achieved.

What is claimed is:

1. A light emitting display device comprising:
a substrate comprising a plurality of subpixels, each of the plurality of subpixels having a light emitting portion and a non-light emitting portion;
a bank configured to open the light emitting portion of each of the plurality of subpixels, the bank being disposed at the non-light emitting portion;
a light emitting device at each of the plurality of subpixels;
an encapsulation layer configured to cover the light emitting device;
an anti-reflective structure comprising a light shielding layer located on the encapsulation layer while overlapping the non-light emitting portion and a color filter located on the encapsulation layer while overlapping the light emitting portion; and
a refractive reinforcement layer located on the anti-reflective structure while overlapping the color filter,
wherein the refractive reinforcement layer has a larger refractive index than the color filter.

2. The light emitting display device according to claim 1, wherein the refractive reinforcement layer overlaps the bank and does not overlap the light shielding layer.

3. The light emitting display device according to claim 1, wherein:
the light shielding layer overlaps a part of the bank, and
the refractive reinforcement layer is disposed between an end line of the light shielding layer and an end line of the bank on a plane.

4. The light emitting display device according to claim 1, wherein:
the light shielding layer overlaps a part of the bank, and
the refractive reinforcing layer overlaps an entirety of the light shielding layer and overlaps the bank with an area equal to or less than an area of the bank.

5. The light emitting display device according to claim 1, wherein the refractive reinforcement layer is disposed at a subpixel configured to emit a green color, among the plurality of subpixels.

6. The light emitting display device according to claim 1, wherein the refractive reinforcement layer abuts an upper surface of the color filter.

7. The light emitting display device according to claim 1, wherein:
the bank comprises a light shielding organic material,
the light shielding layer is provided on a part of the non-light emitting portion, and
the color filter covers an upper surface of the light shielding layer and is disposed so that color filters of adjacent subpixels among the plurality of subpixels abut each other.

8. The light emitting display device according to claim 1, wherein:
the plurality of subpixels comprises a first subpixel having a first light emitting portion configured to emit light of a first wavelength, a second subpixel having a second light emitting portion configured to emit light of a second wavelength shorter than the first wavelength, and a third subpixel having a third light emitting portion configured to emit light of a third wavelength longer than the first wavelength, and
the refractive reinforcement layer is located outside the first light emitting portion while overlapping the first subpixel.

9. The light emitting display device according to claim 8, wherein:
the color filter comprises a green color filter at the first subpixel, a blue color filter at the second subpixel, and a red color filter at the third subpixel, and
the refractive reinforcement layer abuts the green color filter.

10. The light emitting display device according to claim 1, further comprising a refractive adjustment layer on the refractive reinforcement layer, the refractive adjustment layer having a smaller refractive index than the refractive reinforcement layer.

11. The light emitting display device according to claim 10, wherein the refractive adjustment layer and the refractive reinforcement layer have a same width.

12. The light emitting display device according to claim 8, wherein:
the color filter comprises a green color filter at the first subpixel, a blue color filter at the second subpixel, and a red color filter at the third subpixel, and
the light emitting display device further comprises a refractive adjustment layer overlapping the refractive reinforcement layer on the green color filter, the refractive adjustment layer having a smaller refractive index than the refractive reinforcement layer.

13. The light emitting display device according to claim 1, wherein the refractive reinforcement layer has a refractive index of 1.9 or more in a visible light wavelength band.

14. A light emitting display device comprising:
a substrate comprising a red subpixel, a green subpixel, and a blue subpixel, each of the red subpixel, the green subpixel, and the blue subpixel having a light emitting portion and a non-light emitting portion;
a bank configured to open the light emitting portion of each of the red subpixel, the green subpixel, and the blue subpixel, the bank being disposed at the non-light emitting portion;
a light emitting device at each of the red subpixel, the green subpixel, and the blue subpixel;
an encapsulation layer configured to cover the light emitting device;
an anti-reflective structure on the encapsulation layer, the anti-reflective structure comprising a light shielding layer overlapping the non-light emitting portion, a red color filter overlapping the light emitting portion of the red subpixel, a green color filter overlapping the emitting portion of the green subpixel, and a blue color filter overlapping the emitting portion of the blue subpixel; and
a refractive reinforcement layer on the anti-reflective structure, the refractive reinforcement layer at least overlapping the green color filter and having a larger refractive index than the green color filter.

15. The light emitting display device according to claim 14, wherein the refractive reinforcement layer abuts an upper surface of each of the red color filter, the green color filter, and the blue color filter.

16. The light emitting display device according to claim 14, wherein the refractive reinforcement layer overlaps the bank and does not overlap the light shielding layer.

17. The light emitting display device according to claim 14, wherein
the bank comprises a light shielding organic material,
the light shielding layer is provided on a part of the non-light emitting portion,
each of the red color filter, the green color filter, and the blue color filter covers an upper surface of the light shielding layer at the non-light emitting portion, and
one side of the green color filter abuts the red color filter on the upper surface of the light shielding layer, and another side of the green color filter abuts the blue color filter on the upper surface of the light shielding layer.

18. The light emitting display device according to claim 17, further comprising a refractive adjustment layer between the green color filter and the refractive reinforcement layer,
the refractive adjustment layer having a smaller refractive index than the refractive reinforcement layer.

19. The light emitting display device according to claim 14, wherein the refractive reinforcement layer does not overlap the light emitting portion of the green subpixel.
